(19) United States
(12) Patent Application Publication
(10) Pub. No.: US 2017/0167693 A1
(43) Pub. Date: Jun. 15, 2017

(54) LIGHT EMITTING STRUCTURE AND LIGHT EMITTING DEVICE USING THE SAME

(71) Applicant: Sharp Kabushiki Kaisha, Sakai City (JP)

(72) Inventors: Noriyuki YAMAZUMI, Sakai City (JP); Yasutaka KUZUMOTO, Sakai City (JP); Tatsuya RYOHWA, Sakai City (JP); Mami MORISHITA, Sakai City (JP); Makoto IZUMI, Sakai City (JP)

(21) Appl. No.: 15/375,263

(22) Filed: Dec. 12, 2016

(30) Foreign Application Priority Data
Dec. 15, 2015 (JP) 2015-244212
Dec. 15, 2015 (JP) 2015-244213

(51) Int. Cl. F21V 9/16; C09K 11/02

(52) U.S. Cl. CPC F21V 9/16; C09K 11/025; H01L 33/502

(57) ABSTRACT

A light emitting structure comprises a translucent support, a liquid dispersion medium, and a semiconductor nanoparticle phosphor. Preferably, the light emitting structure is formed such that the translucent support has a pore, the liquid dispersion medium is held in the pore of the translucent support, and the semiconductor nanoparticle phosphor is dispersed in the liquid dispersion medium. Furthermore, preferably, the light emitting structure is such that the translucent support includes a macromolecular chain forming a three-dimensional mesh structure, and one or more types of semiconductor nanoparticle phosphors are dispersed in a gelated material including the translucent support and the liquid dispersion medium and presented in a wet state.

This nonprovisional application is based on Japanese Patent Application Nos. 2015-244212 and 2015-244213 filed on Dec. 15, 2015, with the Japan Patent Office, the entire contents of which are hereby incorporated by reference.

### BACKGROUND OF THE INVENTION

1. Field of the Invention

The present invention relates to a light emitting structure including a translucent support, a liquid dispersion medium, and a semiconductor nanoparticle phosphor, as well as a light emitting device using the light emitting structure.

2. Description of the Related Art

A semiconductor nanoparticle phosphor (also referred to as a quantum dot) is of commercial interest for an electron characteristic size-tuneable by a quantum size effect. The size-tuneable electron characteristic is able to be used in a variety of applications such as biological labeling, photovoltaic power generation, catalysis, biological image pick-up, LED, general space lighting, and an electron emission display.

For example, Japanese Patent Laying-Open No. 2014-56896 discloses a light emitting device comprising: a base substrate; a light emitting element provided on the base substrate; a first layer sealing portion formed in at least a part on the light emitting element (a transparent protective layer); and a second layer sealing portion formed in at least a part on the first layer sealing portion (a first fluorescent layer), the second layer sealing portion having two or more types of semiconductor quantum dots (a semiconductor nanoparticle phosphor) (see Japanese Patent Laying-Open No. 2014-56896, claims 1 and 3). In the invention described in Japanese Patent Laying-Open No. 2014-56896, the first layer sealing portion (transparent protective layer) is posed between the light emitting element and the second layer sealing portion including the semiconductor nanoparticle phosphor to alleviate such degradation of the semiconductor nanoparticle phosphor that is caused by the heat of the light emitting element to stabilize the second layer sealing portion.

However, in the light emitting device described in Japanese Patent Laying-Open No. 2014-56896, a phosphor solution in which the semiconductor nanoparticle phosphor is dispersed in a volatile solvent is mixed with a thermosetting epoxy resin, which is in turn dropped on the first layer sealing portion and cured to form the second layer sealing portion (see Japanese Patent Laying-Open No. 2014-56896, paragraphs 0075 and 0078). When the semiconductor nanoparticle phosphor dispersed in the solvent is further dispersed in the resin, the semiconductor nanoparticle phosphor agglomerates or the like resulting in an impaired emission characteristic.

While a semiconductor nanoparticle phosphor dispersed in a liquid dispersion medium allows a highly efficient fluorescent characteristic to be obtained, when it is mixed with a resin material, as in the light emitting device disclosed in Japanese Patent Laying-Open No. 2014-56896, reduced emission efficiency is provided. This is believed to be attributed to a change in an environment surrounding the semiconductor nanoparticle phosphor in the resin, such as agglomeration of semiconductor nanoparticle phosphors, detachment of a surface modifying group, and the like.

The semiconductor nanoparticle phosphor is a colloidal particle and accordingly, for practical use, it is necessary to incorporate a nanoparticle into a sealing material for use, however, even after the semiconductor nanoparticle phosphor is incorporated into the sealing material, the semiconductor nanoparticle phosphor is photooxidized if oxygen permeates the sealing material and moves to a surface of the semiconductor nanoparticle phosphor, and consequently, the semiconductor nanoparticle phosphor's quantum efficiency (QY) would be reduced.

For example, Japanese National Patent Publication No. 2015-509125 discloses, in order to increase a semiconductor nanoparticle phosphor's stability so as to make it brighter, more long-lived and/or less sensitive to various types of processing conditions, a method of fabricating a molded nanoparticle phosphor, the method comprising: providing a suspension of nanoparticles in a matrix material precursor; and converting the suspension to a molded nanoparticle phosphor, the molded nanoparticle phosphor comprising a matrix material and the nanoparticles. The molded nanoparticle phosphor described in Japanese National Patent Publication No. 2015-509125 is able to be formed of the matrix material precursor/the nanoparticles using polymerization molding, contact molding, extrusion or injection molding or any molding technique. Such a molded nanoparticle phosphor may be covered for example with a gas barrier material such as a polymer, metal oxide, metal nitride or a glass.

In the method described in Japanese National Patent Publication No. 2015-509125, the matrix material which disperses the semiconductor nanoparticle phosphor is any material which is able to allow nanoparticles to be dispersed therein and moldable, and polymer, sol gel, epoxy, silicone, acrylate, etc. are indicated as examples. Accordingly, in the method described in Japanese National Patent Publication No. 2015-509125, in a step in molding the matrix material precursor, the semiconductor nanoparticle phosphor has a surface roughened or agglomerates and is thereby impaired in optical performance.

### SUMMARY OF INVENTION

Preferred embodiments of the present invention provide a novel light emitting structure using a semiconductor nanoparticle phosphor, that has high light emission efficiency without causing agglomeration of semiconductor nanoparticle phosphors, detachment of a surface modifying group and the like.

Furthermore, preferred embodiments of the present invention provide a novel light emitting structure which is able to reduce roughening of a surface of a semiconductor nanoparticle phosphor and agglomeration of the semiconductor nanoparticle phosphor and maintain the semiconductor nanoparticle phosphor's excellent optical characteristics.

A light emitting structure according to a preferred embodiment of the present invention is characterized by including a translucent support, a liquid dispersion medium, and a semiconductor nanoparticle phosphor.

The liquid dispersion medium used in the light emitting structure according to various preferred embodiments of the present invention is an ionic liquid.

The liquid dispersion medium used in the light emitting structure according to various preferred embodiments of the present invention is nonvolatile.

The liquid dispersion medium used in the light emitting structure according to various preferred embodiments of the present invention includes at least any of water, toluene, hexane, chloroform, trioctylamine, trioctyl phosphine oxide, 1-octadecene, and an ionic liquid.

The semiconductor nanoparticle phosphor used in the light emitting structure according to various preferred embodiments of the present invention includes a plurality of light emission peaks.

The semiconductor nanoparticle phosphor used in the light emitting structure according to various preferred embodiments of the present invention has a light emission wavelength in a range of about 380 nm to about 750 nm.

The light emitting structure according to various preferred embodiments of the present invention is formed such that the translucent support has a pore, the liquid dispersion medium is held in the pore of the translucent support, and the semiconductor nanoparticle phosphor is dispersed in the liquid dispersion medium.

As the liquid dispersion medium in which the semiconductor nanoparticle phosphor is dispersed is held in the pore of the translucent support without using a resin curing process, a light emitting structure is able to be provided in which changes in an environment surrounding the semiconductor nanoparticle phosphor, such as agglomeration of semiconductor nanoparticle phosphors, detachment of a surface modifying group, and the like, are less likely to occur, so that the semiconductor nanoparticle phosphor remains dispersed in the liquid dispersion medium to be able to stably function and emission characteristics are thus less likely to degrade.

The liquid dispersion medium used in the light emitting structure according to various preferred embodiments of the present invention is held in the pore by capillary force.

The translucent support used in the light emitting structure according to various preferred embodiments of the present invention has a porous structure.

The translucent support used in the light emitting structure according to various preferred embodiments of the present invention is capsular.

The translucent support used in the light emitting structure according to various preferred embodiments of the present invention is a capillary.

The light emitting structure according to a preferred embodiment of the present invention further comprises a covering layer at least covering an opening of the pore.

The translucent support used in the light emitting structure according to various preferred embodiments of the present invention has a gas barrier property.

The present invention also provides a light emitting device comprising a light source and a wavelength converter in which the light emitting structure according to preferred embodiments of the present invention as described above is dispersed in a translucent medium.

The light emitting structure according to a preferred embodiment of the present invention is also formed such that the translucent support includes a macromolecular chain forming a three-dimensional mesh structure, and one or more types of semiconductor nanoparticle phosphors are dispersed in a gelated material including the translucent support and the liquid dispersion medium and presented in a wet state.

Dispersing one or more types of semiconductor nanoparticle phosphors in a gelated material presented in a wet state and including a translucent support including a macromolecular chain forming a three-dimensional mesh structure and a liquid dispersion medium, allows the semiconductor nanoparticle phosphor to be solidified without reacting to the liquid dispersion medium per se. This is able to reduce roughening of a surface of the semiconductor nanoparticle phosphor, and agglomeration of the semiconductor nanoparticle phosphor, and thus provide a light emitting structure (a phosphor containing solidified body) in which the semiconductor nanoparticle phosphor's excellent optical characteristics are maintained. Furthermore, the light emitting structure according to a preferred embodiment of the present invention has flexibility, and is thus expected to be widely used with its flexibility exploited.

The translucent support used in the light emitting structure according a preferred embodiment of the present invention includes at least any material selected from an acrylic acid based polymer, a vinyl based polymer, an epoxy based polymer, a polyvinylidene fluoride-hexafluoro propylene copolymer, a tetrafluoroethylene perfluoro [2-(fluorosulfonyl ethoxy) propylvinyl ether copolymer, poly (2-hydroxyethyl) methacrylate and Tetra-PEG.

The light emitting structure according to a preferred embodiment of the present invention has an outermost surface including a translucent covering layer. In that case, a material included in the covering layer is an inorganic material having a band gap equal to or greater than 3.0 eV.

The light emitting structure according to a preferred embodiment of the present invention is provided in a form of sheet. In that case, preferably, the light emitting structure is accommodated in a capillary.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 schematically shows a light emitting structure 1 of a first embodiment of the present invention.

FIG. 2 is a graph showing a comparison in light emission efficiency between a light emitting structure having a structure shown in FIG. 1 and a case in which the same semiconductor nanoparticle phosphor is dispersed in the same liquid dispersion medium and subsequently mixed with silicone resin.

FIG. 3 schematically shows a light emitting structure 11 of a second embodiment of the present invention.

FIG. 4 schematically shows a light emitting structure 21 of a third embodiment of the present invention.

FIG. 5 schematically shows a light emitting structure 31 of a fourth embodiment of the present invention.

FIG. 6 schematically shows a light emitting structure 41 of a fifth embodiment of the present invention.

FIG. 7A, FIG. 7B, and FIG. 7C schematically show a light emitting structure of a sixth embodiment of the present invention, FIG. 7A showing a light emitting structure 21′ which is an exemplary variation of light emitting structure 21 of the example shown in FIG. 4, FIG. 7B showing a light emitting structure 31′ which is an exemplary variation of light emitting structure 31 of the example shown in FIG. 5, FIG. 7C showing a light emitting structure 41′ which is an exemplary variation of light emitting structure 41 of the example shown in FIG. 6.

FIG. 8 schematically shows a light emitting structure 51 of a seventh embodiment of the present invention.

FIG. 9 schematically shows a light emitting structure 61 of an eighth embodiment of the present invention.

FIG. 10 schematically shows a light emitting structure 71 of a ninth embodiment of the present invention.

FIG. 11 schematically shows a light emitting structure 81 of a tenth embodiment of the present invention.

FIG. 12A and FIG. 12B schematically show light emitting structures 91, 101, 102 of an eleventh embodiment of the present invention.

FIG. 13 schematically shows a light emitting device 111 of a twelfth embodiment of the present invention.

FIG. 14 schematically shows a light emitting device 121 of a thirteenth embodiment of the present invention.

FIG. 15 schematically shows a light emitting structure (a phosphor containing solidified body) 151 of a fourteenth embodiment of the present invention.

FIG. 16 schematically shows a light emitting structure (a phosphor containing solidified body) 161 of a fifteenth embodiment of the present invention.

FIG. 17 schematically shows a light emitting structure (a phosphor containing solidified body) 171 of a sixteenth embodiment of the present invention.

FIG. 18 schematically shows a light emitting structure (a phosphor containing solidified body) 181 of a seventeenth embodiment of the present invention.

FIG. 19 schematically shows a light emitting structure (a phosphor containing solidified body) 191 of an eighteenth embodiment of the present invention.

FIG. 20 schematically shows a light emitting structure (a phosphor containing solidified body) 201 of a nineteenth embodiment of the present invention.

### DESCRIPTION OF THE PREFERRED EMBODIMENTS

<Light Emitting Structure>

A light emitting structure according to a preferred embodiment of the present invention is characterized by including a translucent support, a liquid dispersion medium, and a semiconductor nanoparticle phosphor. Hereinafter, each embodiment is mentioned and a light emitting structure according to a preferred embodiment of the present invention will be specifically described.

(Light Emitting Structure of a First Embodiment)

FIG. 1 schematically shows a light emitting structure 1 of a first embodiment of the present invention. Light emitting structure 1 according to a preferred embodiment of the present invention includes, as shown in an example shown in FIG. 1, a translucent support (translucent base material) 3 having a pore 4, a liquid dispersion medium 5 held in pore 4 of translucent support 3, and a semiconductor nanoparticle phosphor 2 dispersed in liquid dispersion medium 5.

According to the light emitting structure of the first embodiment, as the liquid dispersion medium in which the semiconductor nanoparticle phosphor is dispersed is held in the pore of the translucent support without using a resin curing process, changes in an environment surrounding the semiconductor nanoparticle phosphor, such as agglomeration of semiconductor nanoparticle phosphors, detachment of a surface modifying group, and the like, are less likely to occur, and the semiconductor nanoparticle phosphor remains dispersed in the liquid dispersion medium to be able to stably function and emission characteristics are less likely to degrade. Furthermore, as translucent support 3 surrounds semiconductor nanoparticle phosphor 2 in a state in which it is dispersed in the liquid dispersion medium, semiconductor nanoparticle phosphor 2 is less likely to be exposed to air and moisture, etc., and from such a viewpoint also, the semiconductor nanoparticle phosphor is improved in long-term stability.

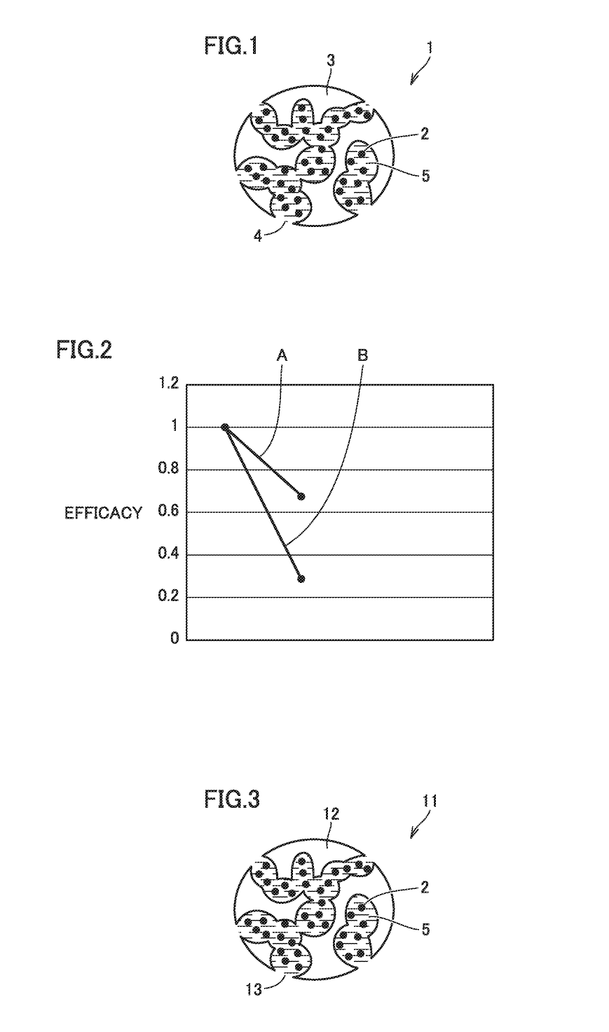

FIG. 2 is a graph representing a comparison in light emission efficiency between the light emitting structure having the structure shown in FIG. 1 (a case where a core shell type CdSe/ZnS having a light emission wavelength of 620 nm is used as the semiconductor nanoparticle phosphor, N,N,N-trimethyl-N-propyl ammonium bis(trifluoromethane sulfonyl)imide is used as the liquid dispersion medium, and Daiso Gel (produced by DAISO Chemical Co., Ltd.) is used as the translucent support) and a case where the same semiconductor nanoparticle phosphor is dispersed in the same liquid dispersion medium and subsequently mixed with a silicone resin (OE-7620 (produced by Dow Corning)) (as measured with C9920-02G (produced by Hamamatsu Photonics)), with an axis of ordinate representing light emission efficiency. In the graph of FIG. 2, A represents the light emitting structure of the first embodiment and B represents the case of mixing with the silicone resin. As is also clear from FIG. 2, when the semiconductor nanoparticle phosphor's efficiency when the semiconductor nanoparticle phosphor is dispersed in the liquid dispersion medium is defined as a reference, B dropped to about 0.3 whereas A stopped at about 0.7. Thus, it can be seen that, in the light emitting structure of the first embodiment, as compared with the case of mixing into the resin, a light emission characteristic of the semiconductor nanoparticle phosphor is less likely to be degraded.

Note that the light emitting structure of the first embodiment has a configuration in which the liquid dispersion medium in which the semiconductor nanoparticle phosphor is dispersed is “held” in the pore of the translucent support, and it is different for example from a configuration in which a liquid in which a semiconductor nanoparticle phosphor is dispersed is “encapsulated” within an outer hollow shell. For encapsulating in the outer hollow shell, the liquid in which the semiconductor nanoparticle phosphor is dispersed is limited, whereas in the present invention configured such that the liquid dispersion medium in which the semiconductor nanoparticle phosphor is dispersed is “held” in the pore of the translucent support, the liquid dispersion medium to be used is not particularly limited.

Semiconductor nanoparticle phosphor 2 in the first embodiment characteristically has high light emission efficiency and a significantly narrow emission line width, its light emission wavelength is controllable by adjusting the nanoparticle's size. In general, satisfactory dispersion in a liquid dispersion medium allows high light emission efficiency, whereas dispersion in a solid such as resin results in agglomeration and energy inactivation between nanoparticle phosphors occurs and efficiency is impaired. Furthermore, by using the semiconductor nanoparticle phosphor, advantageously, an emission wavelength is able to be precisely controlled based on control of composition.

The semiconductor nanoparticle phosphor's source material is not particularly limited, and it may be at least any selected from CdS, CdSe, CdTe, ZnS, ZnSe, ZnTe, InN, InP, InAs, InSb, AlP, AlS, AlAs, AlSb, GaN, GaP, GaAs, GaSb, PbS, PbSe, Si, Ge, MgS, MgSe, MgTe conventionally used as a semiconductor nanoparticle phosphor. Furthermore, the semiconductor nanoparticle phosphor may be a two-component core type, three-component core type, four-component core type, core-shell type or core multishell type, doped or slanted semiconductor nanoparticle phosphor known to those skilled in the art.

The shape of the semiconductor nanoparticle phosphor is not particularly restricted and a semiconductor nanoparticle phosphor including a conventionally known appropriate shape such as a globular shape, a rod shape, or a wire shape, for example, is able to be used without particularly being restricted. In particular, from a point of view of ease in control of light emission characteristics based on control of shape, a globular semiconductor nanoparticle phosphor is preferably used, for example.

The particle size of the semiconductor nanoparticle phosphor is able to be selected as appropriate in accordance with a source material and a desired emission wavelength, without being particularly restricted, however, it is preferably within a range from about 1 nm to about 20 nm and more preferably within a range from about 2 nm to about 5 nm, for example. When the semiconductor nanoparticle phosphor has a particle size smaller than about 1 nm, a ratio of a surface area to a volume tends to increase, a surface defect tends to be dominant, and an effect tends to be lowered. When the semiconductor nanoparticle phosphor has a particle size exceeding about 20 nm, a state of dispersion tends to be low and agglomeration and settling tend to occur. When the semiconductor nanoparticle phosphor has a globular shape, the particle size refers, for example, to an average particle size measured with a particle size distribution analyzer or to a size of a particle observed with an electron microscope. When the semiconductor nanoparticle phosphor has a rod shape, the particle size refers, for example, to a length of a minor axis and a major axis measured with an electron microscope. When the semiconductor nanoparticle phosphor has a wire shape, the particle size refers, for example, to a length of a minor axis and a major axis measured with an electron microscope.

In the light emitting structure of the first embodiment, it is preferable that the semiconductor nanoparticle phosphor disperse within a range of 0.00001 to 100 parts by weight relative to 100 parts by weight of the liquid dispersion medium, and more preferably within a range of 0.001 to 50 parts by weight. This is because when the semiconductor nanoparticle phosphor is less than 0.00001 parts by weight relative to 100 parts by weight of the liquid dispersion medium, the semiconductor nanoparticle phosphor has a low concentration and has a tendency to fail to provide sufficient light emission intensity, whereas when the semiconductor nanoparticle phosphor exceeds 100 parts by weight relative to 100 parts by weight of the liquid dispersion medium, the semiconductor nanoparticle phosphor poorly disperses and semiconductor nanoparticle phosphors have a tendency to easily agglomerate resulting in reduced light emission efficiency.

In the light emitting structure of the first embodiment, the liquid dispersion medium is not particularly limited, however, from the viewpoint of dispersing the semiconductor nanoparticle phosphor stably so that satisfactory light emission efficiency is obtained, an organic dispersion medium, such as toluene, chloroform, hexane, ethanol and methanol, or an aqueous dispersion medium is preferred. Inter alia, an organic dispersion medium having a polarity is able to stably disperse a surface modified semiconductor nanoparticle phosphor, and accordingly, toluene or chloroform is preferably used as the liquid dispersion medium.

Translucent support 3 in the light emitting structure of the first embodiment has translucency and has pore 4. As a material for forming such a translucent support 3, for example as at least one of its major components, silicone resin, epoxy resin, SiO₂, Al₂O₃, ZnO, In₂O₃, SnO₂, TiO₂, etc. are mentioned. Note that FIG. 1 shows an example in which translucent support 3 has pores 4 formed to be at least partially in communication with each other. As such a translucent support 3, a commercially available product may of course be used, and for example, Daiso Gel (produced by DAISO Chemical Co., Ltd.) etc. is mentioned as a suitable example. The contour of translucent support 3 is not particularly limited, and a globe (a sphere and an elliptical globe), a rod, a prism, a film, etc. are mentioned.

Light emitting structure 1 of the first embodiment allows the liquid dispersion medium to be introduced via pore 4 into translucent support 3 and held therein, and accordingly, the liquid dispersion medium is not limited and furthermore, the translucent support's transparency allows excitation light and fluorescent light to be taken in and extracted, without impairing light emission efficiency so that high light emission efficiency, and handleability as a solid (or powder) can be co-established.

(Light Emitting Structure of a Second Embodiment)

FIG. 3 schematically shows a light emitting structure 11 of a second embodiment of the present invention. Note that light emitting structure 11 of the example shown in FIG. 3 has a configuration similar to that of light emitting structure 1 of the example shown in FIG. 1 except for a portion, and any similarly configured portion is identically denoted and will not be described repeatedly. Furthermore, the light emitting structure of the second embodiment includes a translucent support, a liquid dispersion medium, and a semiconductor nanoparticle phosphor, as has been set forth above for the light emitting structure of the first embodiment.

Light emitting structure 11 of the example shown in FIG. 3 has the liquid dispersion medium held in the pore by capillary force. Thus, as in the light emitting structure of the second embodiment, it is preferable that the liquid dispersion medium be held in the pore by capillary force. This prevents the liquid dispersion medium from leaking from the light emitting structure and better handleability is achieved.

In general, a structure having a pore acts to absorb and hold a liquid dispersion medium through capillarity. When the following relational expression is satisfied, an internal liquid can be held through capillarity.

M×g<2πr²×T,

where

M: Mass of liquid dispersion medium [kg]

g: Gravitational acceleration [m/s²]

r: radius of pore [m]

T: surface tension of liquid/side surface [N/m].

When the liquid dispersion medium's type and amount held and the structure's pore diameter establish the above relationship, capillarity manifests, and prevents liquid leakage from the pore and allows the light emitting structure to be easily handled as powder.

(Light Emitting Structure of a Third Embodiment)

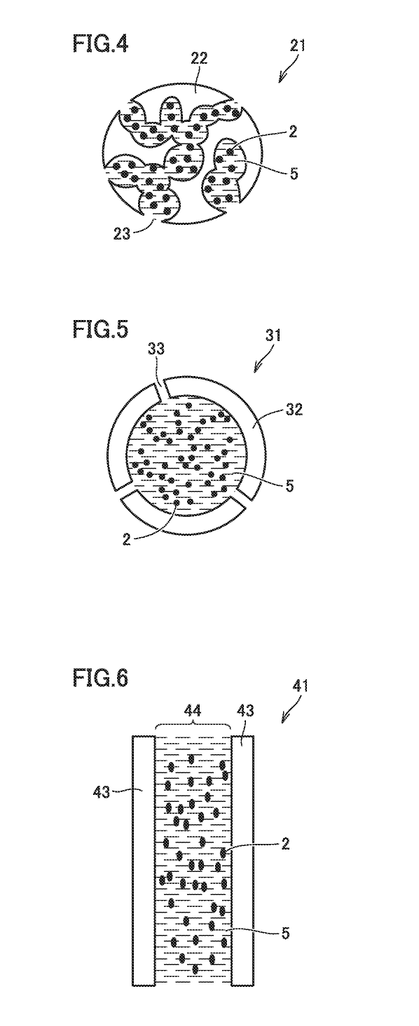

FIG. 4 schematically shows a light emitting structure 21 of a third embodiment of the present invention. Note that light emitting structure 21 of the example shown in FIG. 4 has a configuration similar to that of light emitting structure 1 of the example shown in FIG. 1 except for a portion, and any similarly configured portion is identically denoted and will not be described repeatedly. Furthermore, the light emitting structure of the third embodiment includes a liquid dispersion medium and a semiconductor nanoparticle phosphor, as has been set forth above for the light emitting structure of the first embodiment.

Light emitting structure 21 of the example shown in FIG. 4 includes a translucent support 22 having a porous structure. Herein, the porous structure is a structure characterized by including many pores inside translucent support 22.

Translucent support 22 having the porous structure has many pores and is thus advantageously able to hold the liquid dispersion medium in a large amount in the pores. Furthermore, as the semiconductor nanoparticle phosphor is dispersed in the liquid dispersion medium and thus held in the translucent support having the porous structure, the obtained light emitting structure is able to be handled as a solid fluorescent member and is able to be further dispersed in a resin easily.

Translucent support 22 which has the porous structure is obtained for example as follows: As a material for forming the translucent support, a sol-gel precursor (such as metal alkoxide) and a surfactant are mixed together in water, a network of silica is formed through water decomposition, condensation, etc., and a heat treatment is done to remove an organic template to obtain a translucent support which has a porous structure having pores and including silica as a major component. Alternatively, as translucent support 3 having a porous structure, a commercially available product may of course be used, and for example, Daiso Gel (produced by DAISO Chemical Co., Ltd.), M.S. GEL (produced by AGC Si-Tech. Co., Ltd.) etc. are mentioned as suitable examples.

(Light Emitting Structure of a Fourth Embodiment)

FIG. 5 schematically shows a light emitting structure 31 of a fourth embodiment of the present invention. Note that light emitting structure 31 of the example shown in FIG. 5 has a configuration similar to that of light emitting structure 1 of the example shown in FIG. 1 except for a portion, and any similarly configured portion is identically denoted and will not be described repeatedly. Furthermore, the light emitting structure of the fourth embodiment includes a liquid dispersion medium and a semiconductor nanoparticle phosphor, as has been set forth above for the light emitting structure of the first embodiment.

Light emitting structure 31 of the fourth embodiment may use a capsular translucent support 32, as shown in the example shown in FIG. 5. In that case, translucent support 32 has a pore 33 in communication with an internal space, and in that internal space, liquid dispersion medium 5 which has semiconductor nanoparticle phosphor 2 dispersed therein and is introduced via pore 33 is accommodated. When using such a capsular translucent support 32 is compared with the embodiment shown in FIG. 1, the former is advantageous in that the support has a large vacancy capacity per volume and thus helps to allow the semiconductor nanoparticle phosphor to be held in the liquid dispersion medium of a large amount.

As such a capsular translucent support 32, what includes a material such as silica is able to be suitably used for example. Furthermore, as such a capsular translucent support 32, a commercially available product may of course be used.

(Light Emitting Structure of a Fifth Embodiment)

FIG. 6 schematically shows a light emitting structure 41 of a fifth embodiment of the present invention. Note that light emitting structure 41 of the example shown in FIG. 6 has a configuration similar to that of light emitting structure 1 of the example shown in FIG. 1 except for a portion, and any similarly configured portion is identically denoted and will not be described repeatedly. Furthermore, the light emitting structure of the fifth embodiment includes a liquid dispersion medium and a semiconductor nanoparticle phosphor, as has been set forth above for the light emitting structure of the first embodiment.

Light emitting structure 41 of the fifth embodiment may be implemented such that it includes a capillary translucent support 43 (a cylindrical structure having a pore), as shown in the example shown in FIG. 6, and in its internal space (or a pore) 44, liquid dispersion medium 5 which has semiconductor nanoparticle phosphor 2 dispersed therein is accommodated. When using such a capillary translucent support 43 is compared with the embodiment shown in FIG. 1, the former is advantageous in that by aligning an arrayed excitation source and the capillary, the light emitting structure is able to be easily used for a back light for a display of an edge type.

As such a capillary translucent support 43, what includes a material such as silica is able to be suitably used for example. Furthermore, as such a capillary translucent support 43, a commercially available product may of course be used, and for example, DURAN Capillary (produced by SCHOTT AG) etc. is mentioned as a suitable example.

(Light Emitting Structure of a Sixth Embodiment)

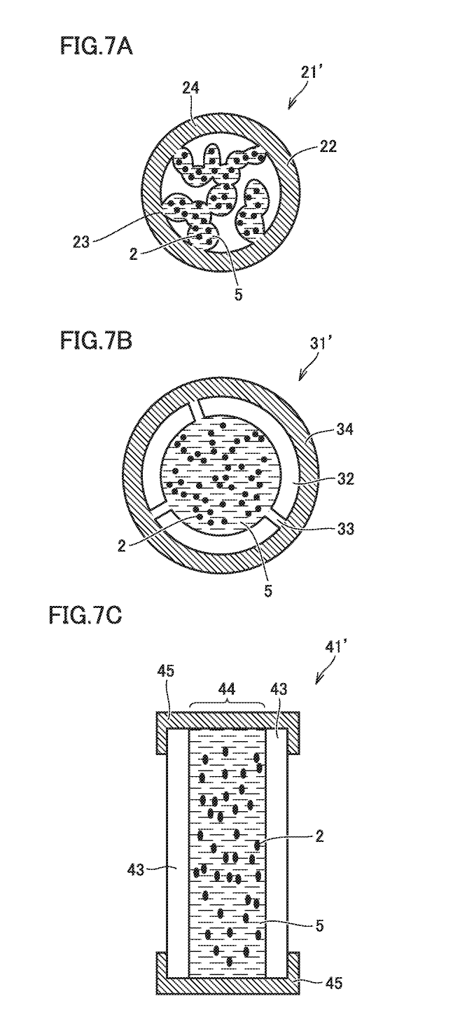

FIG. 7A, FIG. 7B, and FIG. 7C schematically show a light emitting structure of a sixth embodiment of the present invention, FIG. 7A showing a light emitting structure 21′ which is an exemplary variation of light emitting structure 21 of the example shown in FIG. 4, FIG. 7B showing a light emitting structure 31′ which is an exemplary variation of light emitting structure 31 of the example shown in FIG. 5, FIG. 7C showing a light emitting structure 41′ which is an exemplary variation of light emitting structure 41 of the example shown in FIG. 6. Note that light emitting structures 21′, 31′ and 41′ of the examples shown in FIG. 7A, FIG. 7B and FIG. 7C are similarly configured except for furthermore including covering layers (protective base materials) 24, 34, and 45 to at least cover the structures' respective pores' openings, and any similarly configured portion is identically denoted and will not be described repeatedly. Furthermore, the light emitting structure of the sixth embodiment includes a translucent support, a liquid dispersion medium, and a semiconductor nanoparticle phosphor, as has been set forth above for the light emitting structure of the first embodiment.

Thus, liquid dispersion medium 5 having semiconductor nanoparticle phosphor 2 dispersed therein is held inside translucent supports having pores 23, 33, 44 and covering layers 24, 34 and 45 are subsequently applied to at least close pores 23, 33, 44 to effectively prevent gas from entering the pores and thus allow the semiconductor nanoparticle phosphor to emit light efficiently for a long period of time more stably. Furthermore, covering layers 24, 34 and 45 are able to physically prevent the liquid dispersion medium from leaking from the light emitting structure and thus enhance the light emitting structure's handleability.

Furthermore, when the liquid dispersion medium having the semiconductor nanoparticle phosphor dispersed therein is directly covered with the covering layer and thus encapsulated therein, the liquid dispersion medium to be encapsulated is limited, and the method to do so is also limited such as coacervation for example. In contrast, in the case of the light emitting structures of the examples shown in FIG. 7A, FIG. 7B and FIG. 7C, a translucent support having a pore is caused to hold a liquid dispersion medium having a semiconductor nanoparticle phosphor dispersed therein, and in that condition, a covering layer is provided to at least cover the pore's opening, so that for example the covering layer is able to be easily provided in such a manner which attaches a film to a solid, and there is no particular limitation on the method of providing the covering layer and there is no particular limitation, either, on the type of the liquid dispersion medium used.

Note that the covering layer is only required to be provided to at least close the pore, and as shown in the examples shown in FIG. 7A and FIG. 7B, it may be provided to cover the light emitting structure's outermost shell entirely, or as shown in the example shown in FIG. 7C, it may be provided to only cover the pore.

There is no particular limitation on a material used to form the covering layer, and for example as at least one of its major components, silicone resin, epoxy resin, SiO₂, Al₂O₃, ZnO, In₂O₃, SnO₂, TiO₂, etc. are mentioned. Inter alia, for better workability and high stability, it is preferable to use a covering layer including silicone resin. Furthermore, as such a covering layer, a commercially available product may of course be used, and for example, KER-2500 (produced by Shin-Etsu Chemical Co., Ltd.) etc. is mentioned as a suitable example.

(Light Emitting Structure of a Seventh Embodiment)

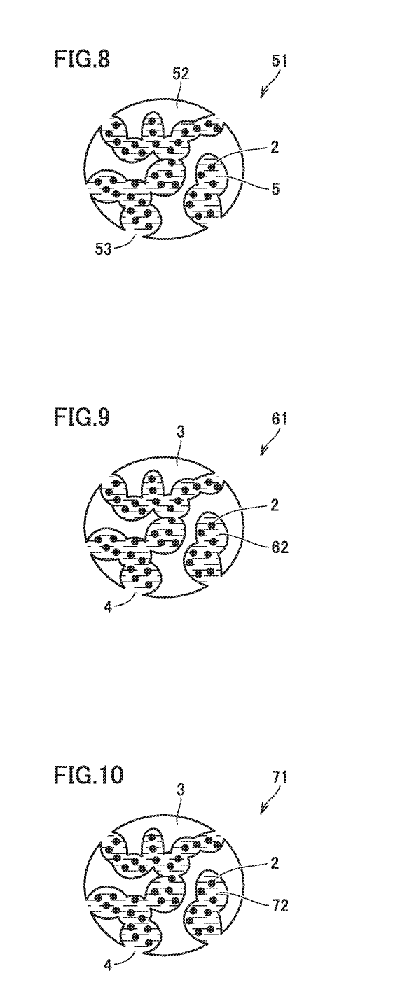

FIG. 8 schematically shows a light emitting structure 51 of a seventh embodiment of the present invention. Note that light emitting structure 51 of the example shown in FIG. 8 has a configuration similar to that of light emitting structure 1 of the example shown in FIG. 1 except for a portion, and any similarly configured portion is identically denoted and will not be described repeatedly. Furthermore, the light emitting structure of the seventh embodiment includes a liquid dispersion medium and a semiconductor nanoparticle phosphor, as has been set forth above for the light emitting structure of the first embodiment.

Light emitting structure 51 of the example shown in FIG. 8 includes a translucent support 52 having a gas barrier property. Herein, the “gas barrier property” indicates that oxygen permeability as measured using coulometry, gas chromatography or the like is equal to or less than 10000 cc/m²/day (more suitably, within a range of 0 to 300 cc/m²/day). With translucent support 52 having such a gas barrier property, gas is less likely to enter pore 53 regarding a portion excluding the pore's opening, and accordingly, the semiconductor nanoparticle phosphor is less likely to be degraded by gas and is thus advantageously able to emit light efficiently for a long period of time stably.

As a material used to form translucent support 52 having such a gas barrier property, for example as at least one of its major components, silicone resin, epoxy resin, SiO₂, Al₂O₃, In₂O₃, SnO₂, TiO₂, ZnO, etc. are mentioned. Inter alia, having low oxygen permeability is preferred, and as a translucent support which has a gas barrier property, it is preferable to use a translucent support including a modified silicone resin. Furthermore, as a translucent support having such a gas barrier property, a commercially available product may of course be used, and for example, OE-7620 (produced by Dow Corning), SS-6503 (produced by SANYU REC. LTD.), etc. are mentioned as suitable examples.

(Light Emitting Structure of an Eighth Embodiment)

FIG. 9 schematically shows a light emitting structure 61 of an eighth embodiment of the present invention. Note that light emitting structure 61 of the example shown in FIG. 9 has a configuration similar to that of light emitting structure 1 of the example shown in FIG. 1 except for a portion, and any similarly configured portion is identically denoted and will not be described repeatedly. Furthermore, the light emitting structure of the eighth embodiment includes a translucent support and a semiconductor nanoparticle phosphor, as has been set forth above for the light emitting structure of the first embodiment.

In light emitting structure 61 of the example shown in FIG. 9, a nonvolatile liquid dispersion medium is used as a liquid dispersion medium 62 to disperse the semiconductor nanoparticle phosphor therein. Herein, being “nonvolatile” indicates a liquid having a high boiling point (suitably, 100° C. or more). As a suitable example of such a nonvolatile liquid dispersion medium, isobutyl alcohol, toluene, xylene, ethylene glycol monoethyl ether, etc. are mentioned, for example.

When a nonvolatile liquid dispersion medium is used as in the light emitting structure of the eighth embodiment, the liquid dispersion medium is less likely to evaporate in a state where the liquid dispersion medium is held in the pore of the light emitting structure, and it thus becomes easy to maintain the state where the liquid dispersion medium is held in the pore, and furthermore, the semiconductor nanoparticle phosphor's degradation attributed to the liquid dispersion medium's evaporation can be prevented.

(Light Emitting Structure of a Ninth Embodiment)

FIG. 10 schematically shows a light emitting structure 71 of a ninth embodiment of the present invention. Note that light emitting structure 71 of the example shown in FIG. 10 has a configuration similar to that of light emitting structure 1 of the example shown in FIG. 1 except for a portion, and any similarly configured portion is identically denoted and will not be described repeatedly. Furthermore, the light emitting structure of the ninth embodiment includes a translucent support and a semiconductor nanoparticle phosphor, as has been set forth above for the light emitting structure of the first embodiment.

In light emitting structure 71 of the example shown in FIG. 10, an ionic liquid is used as a liquid dispersion medium 72 to disperse the semiconductor nanoparticle phosphor therein. An ionic liquid characteristically does not have vapor pressure and substantially does not evaporate, and is able to be better held than the nonvolatile liquid dispersion medium. Furthermore, the ionic liquid has an effect to electrostatically stabilize the semiconductor nanoparticle phosphor's surface and stably disperse the semiconductor nanoparticle phosphor without agglomeration, and a light emitting structure which presents high light emission efficiency and brightness is obtained.

As the ionic liquid which may be used for light emitting structure 71 of the ninth embodiment, for example, 2-(methacryloyloxy)-ethyltrimethyl ammonium bis(trifluoromethane sulfonyl)imide, 1-(3-acryloyloxy-propyl)-3-methylimidazolium bis(trifluoromethanesulfonyl) imide, N,N,N-trimethyl-N-propyl ammonium bis(trifluoromethane sulfonyl) imide, N,N-dimethyl-N-methyl-2-(2-methoxy ethyl) ammonium bis(trifluoromethane sulfonyl)imide, 1-allyl-3-butyl imidazolium tetrafluoroborate, 1-methyl-3-octylimidazolium hexafluoromethanephosphate, etc, are mentioned. Among these, an ionic liquid including impurity such as water tends to decrease the semiconductor nanoparticle phosphor's long-term stability, and accordingly, as the ionic liquid, it is preferable to use N,N,N-trimethyl-N-propyl ammonium bis(trifluoromethane sulfonyl) imide, as it is hydrophobic and is able to easily separate water.

(Light Emitting Structure of a Tenth Embodiment)

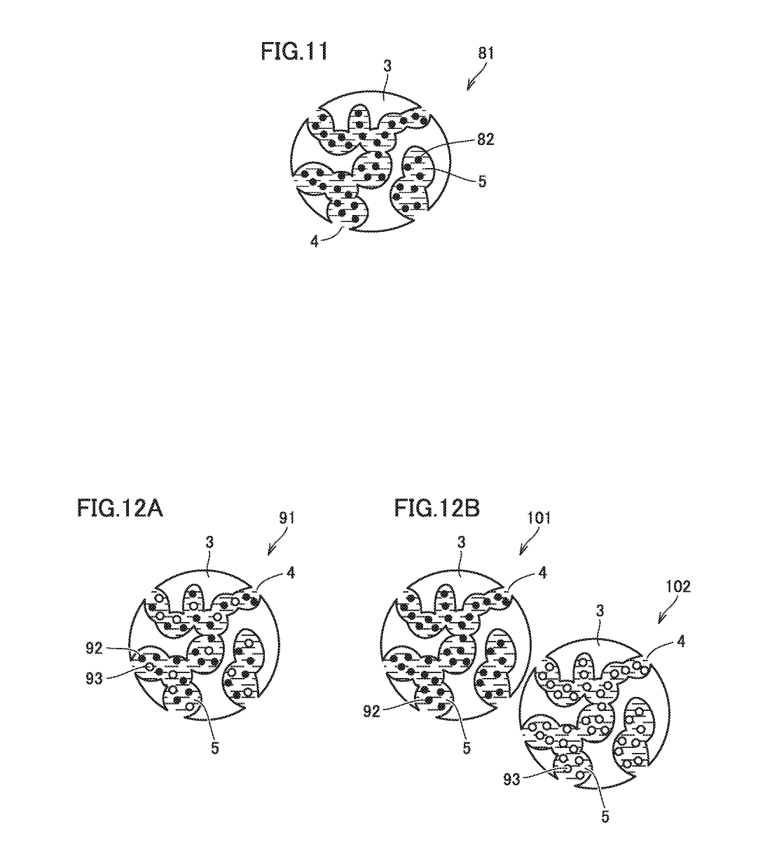

FIG. 11 schematically shows a light emitting structure 81 of a tenth embodiment of the present invention. Note that light emitting structure 81 of the example shown in FIG. 11 has a configuration similar to that of light emitting structure 1 of the example shown in FIG. 1 except for a portion, and any similarly configured portion is identically denoted and will not be described repeatedly. Furthermore, the light emitting structure of the tenth embodiment includes a translucent support and a liquid dispersion medium, as has been set forth above for the light emitting structure of the first embodiment.

In the example shown in FIG. 11, a semiconductor nanoparticle phosphor 82 having a light emission wavelength in a range of about 380 nm to about 750 nm (i.e., having a band gap which emits visible light) is used. Using the semiconductor nanoparticle phosphor having such a light emission wavelength is advantageous in that when it is used in combination with an excitation light source such as a blue LED a light source having any color nuance is able to be obtained. When a semiconductor nanoparticle phosphor having a light emission wavelength less than 380 nm or exceeding 750 nm is used, the wavelength is outside the visible light region and a substantially black color is observed, and the semiconductor nanoparticle phosphor is unsuitable as a phosphor for obtaining a light source of any color nuance.

As semiconductor nanoparticle phosphor 82 which has the above light emission wavelength, at least one type selected from InP, InN, InAs, InSb, InBi, ZnO, In₂O₃, Ga₂O₃, ZrO₂, In₂S₃, Ga₂S₃, In₂Se₃, Ga₂Se₃, In₂Te₃, Ga₂Te₃, CdSe, CdTe, CdS, etc. is mentioned. Note that such a semiconductor nanoparticle phosphor 82 may be a semiconductor nanoparticle phosphor having a conventionally known appropriate shape such as a globular shape, a rod shape, and a wire shape, similarly as has been set forth above.

(Light Emitting Structure of an Eleventh Embodiment)

FIG. 12A and FIG. 12B schematically show light emitting structures 91, 101, 102 of an eleventh embodiment of the present invention. Note that light emitting structures 91, 101, 102 of the examples shown in FIG. 12A and FIG. 12B have a configuration similar to that of light emitting structure 1 of the example shown in FIG. 1 except for a portion, and any similarly configured portion is identically denoted and will not be described repeatedly. Furthermore, the light emitting structure of the eleventh embodiment includes a translucent support and a liquid dispersion medium, as has been set forth above for the light emitting structure of the first embodiment.

A light emitting structure having a plurality of light emission peaks is advantageous in that it facilitates adjustment to a target emission spectrum. For example, when a light emitting structure which has a red light emission peak and a green light emission peak is used in combination with a blue excitation light source, white light having a good color rendering property is able to be easily implemented. The light emitting structure having a plurality of light emission peaks may be implemented for example by dispersing two types of semiconductor nanoparticle phosphors having mutually different light emission peaks (e.g., a red light emitting semiconductor nanoparticle phosphor and a green light emitting semiconductor nanoparticle phosphor) 92 and 93 in a liquid dispersion medium, as in light emitting structure 91 of the example shown in FIG. 12. Furthermore, as shown in the example shown in FIG. 12B, by using two types of light emitting structures 101 and 102 in which semiconductor nanoparticle phosphors having mutually different light emission peaks (e.g., a red light emitting semiconductor nanoparticle phosphor and a green light emitting semiconductor nanoparticle phosphor) 92 and 93 are dispersed in liquid dispersion media held in separate translucent base materials 3, respectively, a light emitting structure having a plurality of light emission peaks may be implemented.

<Light Emitting Device>

(Light Emitting Device of a Twelfth Embodiment)

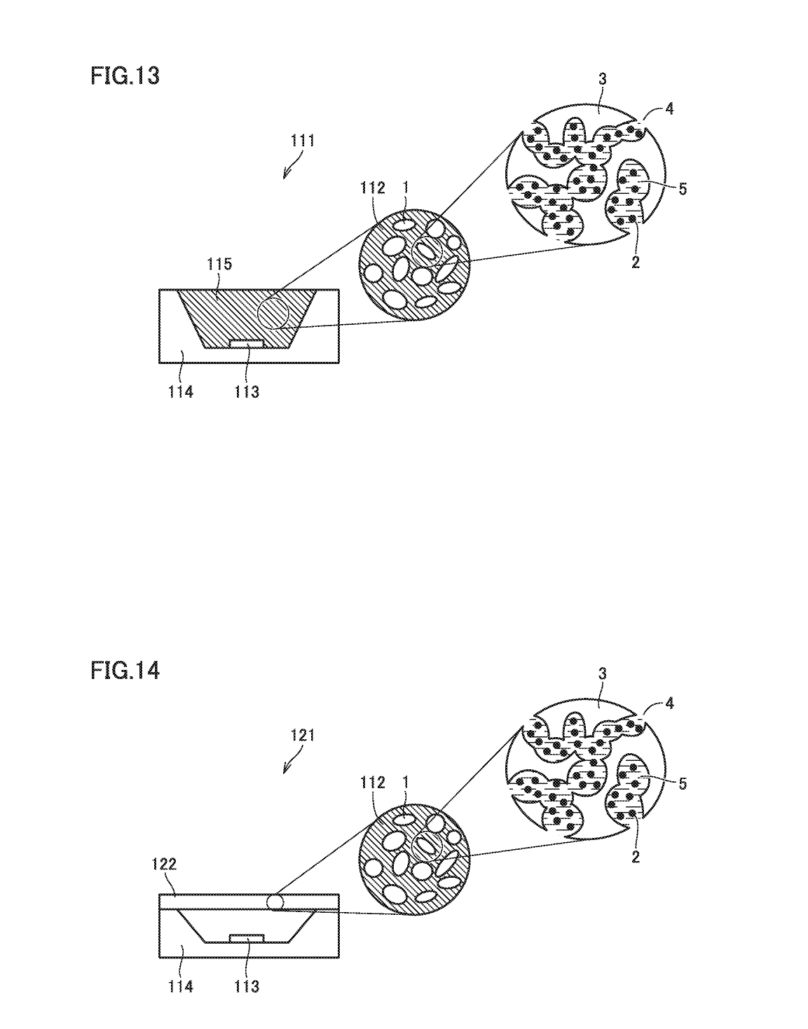

FIG. 13 schematically shows a light emitting device 111 of a twelfth embodiment of the present invention. The present invention also provides light emitting device (LED package) 111 including a light source 113 and a wavelength converter 112 in which any of the light emitting structures of the first to eleventh embodiments is dispersed in a translucent medium 115. The light emitting structure according to a preferred embodiment of the present invention is good in handleability, and by producing it in a size approximately the same as a currently used phosphor, it is able to be used in a form similar to that of a currently commercially used phosphor without changing a currently used process. In the light emitting device shown in FIG. 13, components other than the light emitting structure, i.e., light source 113, translucent medium 115, a frame body 114, a lead wire, etc. are not particularly limited and are able to be conventionally known, appropriate components. Light emitting device 111 according to a preferred embodiment of the present invention of the example shown in FIG. 13 has frame body 114 having a recess with light source 113 mounted thereon, and the wavelength converter is such that the recess, including the light source, is filled with the medium.

In the light emitting device according to a preferred embodiment of the present invention, the light source is not particularly limited, and a light emitting diode (LED), a laser diode (LD), etc. are able to be used.

In light emitting device 111 according to a preferred embodiment of the present invention, a translucent medium for sealing light source 113 and the light emitting structure is not particularly limited, and epoxy, silicone and (meth)acrylate, silica glass, silica gel, siloxane, sol-gel, hydrogel, agarose, cellulose, epoxy, polyether, polyethylene, polyvinyl, polydiacetylene, polyphenylene vinylene, polystyrene, polypyrrole, polyimide, polyimidazole, polysulfone, polythiophene, polyphosphate, poly(meth)acrylate, polyacrylamide, polypeptide, polysaccharide, etc. are mentioned. A plurality of these may be combined and thus used as a translucent medium.

(Light Emitting Device of a Thirteenth Embodiment)

FIG. 14 schematically shows a light emitting device 121 of a thirteenth embodiment of the present invention. Light emitting device 121 of the example shown in FIG. 14 has frame body 114 having a recess with light source 113 mounted therein, and wavelength converter 112 is a film-like object 122 which covers at least a portion of an opening of the recess. When using such a film-like object 122 as wavelength converter 112 is compared with a case where the recess, including the light source, is filled with the medium, as shown in FIG. 13, the former has the excitation light source and the wavelength converter disposed such that the recess's internal space is introduced, which is advantageous in that such an effect is expected that an effect of the heat from the excitation light source is alleviated and the semiconductor nanoparticle phosphor included in the wavelength converter is improved in long-term stability. The film-like object used as the wavelength converter is able to be produced using a conventionally known appropriate material and a conventionally known appropriate method, and the material and the method are not particularly limited.

<Light Emitting Structure (Phosphor Containing Solidified Body)>

(Light Emitting Structure of a Fourteenth Embodiment (Phosphor Containing Solidified Body))

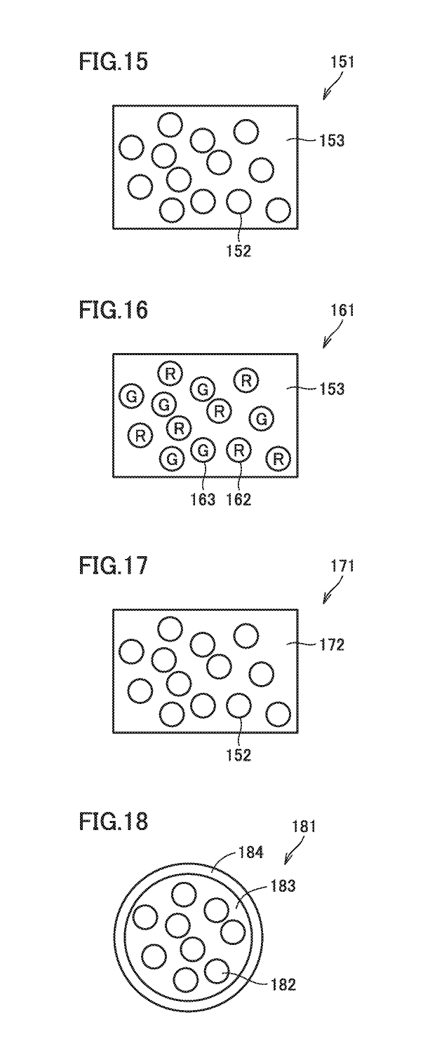

FIG. 15 schematically shows a light emitting structure (a phosphor containing solidified body) 151 of a fourteenth embodiment of the present invention. Light emitting structure 151 of the fourteenth embodiment is characterized in that one or more types of semiconductor nanoparticle phosphors 152 are dispersed in a gelated material 153 in a wet state including a translucent support including a macromolecular chain forming a three-dimensional mesh structure and a liquid dispersion medium, as shown in the example shown in FIG. 15.

The translucent support used for the gelated material in light emitting structure 151 of the fourteenth embodiment is not particularly limited as long as it is formed of a macromolecular chain forming a three-dimensional mesh structure, and for example, at least any selected from an acrylic acid based polymer, a vinyl based polymer, an epoxy based polymer, a polyvinylidene fluoride-hexafluoro propylene copolymer (PVDF-HFP), a tetrafluoroethylene perfluoro [2-(fluorosulfonyl ethoxy) propylvinyl ether copolymer, poly (2-hydroxyethyl) methacrylate and Tetra-PEG is mentioned as a preferred example. Other than these, a conventionally known appropriate rubber material, protein, polysaccharide, etc. may also be used as the translucent support in the present invention in an applicable range, however, for high chemical stability, a translucent support formed at least any selected from the above mentioned acrylic acid based polymer, vinyl based polymer, epoxy based polymer, polyvinylidene fluoride-hexafluoro propylene copolymer (PVDF-HFP), tetrafluoroethylene perfluoro [2-(fluorosulfonyl ethoxy) propylvinyl ether copolymer, poly (2-hydroxyethyl) methacrylate and Tetra-PEG is preferably used.

Herein, the acrylic acid based polymer refers to a polymer of acrylic ester or methacrylic ester, and for example, poly [2-acrylamide 2-methylpropanesulfonic acid] (PAMPS), polyacrylamide (PAAm), sodium polyacrylate, polyacrylic acid, ammonium polyacrylate, crosslinked sodium polyacrylate, crosslinked polyacrylic acid, polymethyl methacrylate and the like are indicated as examples.

The vinyl based polymer refers to a polymer of a vinyl compound, and for example, polyvinyl alcohol, polyethylene, polyvinyl chloride, polystyrene, polyacrylonitrile, polypropylene, polyvinyl acetate, polyvinyl fluoride, polyvinylidene chloride, ethylene-vinylalcohol copolymer, etc. are indicated as examples.

The epoxy based polymer refers to a thermosetting resin that is able to be set by being crosslinked and thus networked by an epoxy group caused to remain in a macromolecule, and for example, bisphenol F type epoxy resin, polyfunctional epoxy resin, flexible epoxy resin, brominated epoxy resin, macromolecular type epoxy resin, biphenyl type epoxy resin, etc. are indicated as examples.

Of the above, a tetrafluoroethylene perfluoro [2-(fluorosulfonyl ethoxy) propylvinyl ether copolymer is a copolymer of a fluororesin with a sulfonated tetrafluoroethylene serving as a base, and a commercially available product such as Nafion (registered trademark) is known. Furthermore, of the above, Tetra-PEG is obtained by causing two types of 4-arm polyethylene glycols having an amine terminal and an N-hydroxysuccinimide (NHS) terminal (active ester terminal), respectively to undergo an inter-terminal crosslinking reaction.

Furthermore, the translucent support may of course be of a combination of a plurality of those mentioned above, and for example, when, of the above indicated as acrylic polymers, hard and brittle poly [2-acrylamide 2-methylpropanesulfonic acid] (PAMPS) and flexibly variable, neutral polyacrylamide (PAAm) are combined together, a translucent support which has a double network structure and has high mechanical strength is able to be provided.

That light emitting structure 151 of the fourteenth embodiment is such that the translucent support in the gelated material in the wet state forms a three-dimensional mesh structure is able to be confirmed for example by constructing a three dimensional image based on a sliced image observed with a cofocal laser scanning microscope (LSCM). Note that the mesh structure's mesh is not particularly limited in size, however, for the reason that the semiconductor nanoparticle phosphor is easily held, a range of about 5 to about 100 nm is preferable and a range of about 10 to about 30 nm is more preferable. Note that the size of the mesh of the translucent support is able to be obtained for example by measuring a diffusion coefficient D through scanning electron microscope scattering, dynamic light scattering or the like, and using a relational expression of diffusion coefficient D and a correlation length representing the size of the mesh of the gel:

$$D = \frac{{k}_{B} T}{6 πηξ}$$

where k_{B} represents a Boltzmann's factor and η represents the liquid dispersion medium's viscosity.

The liquid dispersion medium included in the gelated material in light emitting structure 151 of the fourteenth embodiment is not particularly limited as long as it is a liquid which is usable to disperse the semiconductor nanoparticle phosphor, and for example, water, toluene, hexane, chloroform, trioctylamine, trioctylphosphine, trioctylphosphine oxide, 1-octadecene and other similar organic solvents, an ionic liquid (described later), etc. are indicated. Inter alia, toluene, hexane or a similar organic solvent, or the ionic liquid is preferably used as the liquid dispersion medium as it allows a particularly high light emission characteristic to be obtained when the semiconductor nanoparticle phosphor is dispersed therein.

The gelated material in the wet state in light emitting structure 151 of the fourteenth embodiment indicates what includes a translucent support including a macromolecular chain forming a three-dimensional mesh structure as described above and a liquid dispersion medium. A gel (dry gel), such as silica gel, obtained in a so-called sol-gel method such that through sol-gel hydrolysis and dehydration condensation a dispersoid forms a network is not encompassed in “the gelated material in the wet state” in the fourteenth embodiment. Note that, that the gelated material is in the “wet state” indicates that a liquid content calculated by (weight of gel caused to contain liquid minus weight of gel dried)/weight of gel caused to contain liquid×100 is 10% or more.

The gelated material in the wet state in light emitting structure 151 of the fourteenth embodiment is not particularly limited in shape, and it is formed in a sheet, a globe, a fiber, a disk, a rod, an oval, a cube, a rectangular parallelepiped, etc.

The gelated material in the wet state in light emitting structure 151 of the fourteenth embodiment is not particularly limited regarding the ratio of the translucent support and the liquid dispersion medium, however, in a weight ratio, the liquid dispersion medium is preferably within a range from about 20 to about 100000 and more preferably within a range from about 50 to about 10000, with the translucent support being defined as 100. When in a weight ratio the liquid dispersion medium is about 20 or less with the translucent support being defined as 100, the gelated material has a tendency to be small in flexibility, whereas when in a weight ratio the liquid dispersion medium exceeds about 100000 with the translucent support being defined as 100, the gelated material has a tendency to be small in mechanical strength. The ratio of the translucent support and the liquid dispersion medium in the gelated material in the wet state can be obtained by measuring the weight of the gelated material in the wet state and that of the gelated material in a dry state, for example.

Semiconductor nanoparticle phosphor 152 in light emitting structure 151 of the fourteenth embodiment is as has been described above for the light emitting structure of the first embodiment.

In light emitting structure 151 of the fourteenth embodiment, it is preferable that the semiconductor nanoparticle phosphor disperse within a range of about 0.00001 to about 100 parts by weight relative to 100 parts by weight of the liquid dispersion medium, and more preferably within a range of about 0.001 to about 50 parts by weight. This is because when the semiconductor nanoparticle phosphor is less than about 0.00001 parts by weight relative to 100 parts by weight of the liquid dispersion medium, the semiconductor nanoparticle phosphor has a low concentration and has a tendency to fail to provide sufficient light emission intensity, whereas when the semiconductor nanoparticle phosphor exceeds about 100 parts by weight relative to 100 parts by weight of the liquid dispersion medium, the semiconductor nanoparticle phosphor poorly disperses and semiconductor nanoparticle phosphors have a tendency to easily agglomerate resulting in reduced light emission efficiency.

According to light emitting structure 151 of the fourteenth embodiment the semiconductor nanoparticle phosphor is dispersed in a gelated material in a wet condition, and is thus able to be dispersed without degradation and agglomeration. This is able to reduce roughening of a surface of the semiconductor nanoparticle phosphor, and agglomeration of the semiconductor nanoparticle phosphor, and thus provide a light emitting structure in which the semiconductor nanoparticle phosphor's excellent optical characteristics are maintained. Furthermore, light emitting structure 151 of the fourteenth embodiment that uses a gelated material in a wet state is higher in optical transparency than a case using a dry gel. Furthermore, the wet gelated material is more elastic than the dry gel and accordingly, advantageously able to be adhered to a member (i.e., as it is flexible, it is able to be easily adhered to a curved surface etc.), and is thus expected to be widely used with its flexibility exploited. Furthermore, when compared with the case using a dry gel, using a highly thermally conductive liquid dispersion medium is advantageous in capable of increasing thermal conductivity and thus being advantageous in dissipating heat generated from the semiconductor nanoparticle phosphor.

The gelated material in the wet state in light emitting structure 151 of the fourteenth embodiment is able to be produced in a conventionally known appropriate method. For example, a precursor of the translucent support in a state before it forms the three-dimensional mesh structure and the liquid dispersion medium with the semiconductor nanoparticle phosphor dispersed therein are mixed together and then heated under an appropriate condition or the like so that the translucent support forms the three-dimensional mesh structure. Furthermore, the translucent support which has already formed the three-dimensional mesh structure and the liquid dispersion medium with the semiconductor nanoparticle phosphor dispersed therein may be mixed together. Furthermore, as another method, for example, the liquid dispersion medium with the semiconductor nanoparticle phosphor dispersed therein may be partially crosslinked to provide the translucent support, or a low-molecular gelling agent may be added to the liquid dispersion medium with the semiconductor nanoparticle phosphor dispersed therein to provide a gelated material in a wet state. Note that the size of the mesh in the three-dimensional mesh structure of the translucent support is adjustable for example by whether a crosslinking agent is added or not.

(Light Emitting Structure of a Fifteenth Embodiment (Phosphor Containing Solidified Body))

FIG. 16 schematically shows a light emitting structure (a phosphor containing solidified body) 161 of a fifteenth embodiment of the present invention. Note that light emitting structure 161 of the example shown in FIG. 16 has a configuration similar to that of light emitting structure 151 of the example shown in FIG. 15 except for a portion, and any similarly configured portion is identically denoted and will not be described repeatedly. Furthermore, the light emitting structure of the fifteenth embodiment includes a translucent support and a liquid dispersion medium, as has been set forth above for the light emitting structure of the fourteenth embodiment.

Light emitting structure 161 of the example shown in FIG. 16 differs from light emitting structure 151 of the example shown in FIG. 15 in that two types of semiconductor nanoparticle phosphors 162, 163 are dispersed in gelated material 153 in a wet state. A light emitting structure having a plurality of light emission peaks is advantageous in that it facilitates adjustment to a target emission spectrum. For example, when a light emitting structure in which two types of semiconductor nanoparticle phosphors having a red light emission peak and a green light emission peak are combined is used in combination with a blue excitation light source, white light having a good color rendering property is able to be easily implemented. In the example shown in FIG. 16, for example, two types of semiconductor nanoparticle phosphors having mutually different light emission peaks (e.g., red light emitting semiconductor nanoparticle phosphor 162 and green light emitting semiconductor nanoparticle phosphor 163) are dispersed in gelated material 153 in the wet state.

(Light Emitting Structure of a Sixteenth Embodiment (Phosphor Containing Solidified Body))

FIG. 17 schematically shows a light emitting structure (a phosphor containing solidified body) 171 of a sixteenth embodiment of the present invention. Note that light emitting structure 171 of the example shown in FIG. 17 has a configuration similar to that of light emitting structure 151 of the example shown in FIG. 15 except for a portion, and any similarly configured portion is identically denoted and will not be described repeatedly. Furthermore, the light emitting structure of the sixteenth embodiment includes a translucent support and a semiconductor nanoparticle phosphor, as has been set forth above for the light emitting structure of the fourteenth embodiment.

In light emitting structure 171 of the example shown in FIG. 17, an ionic liquid is used as a liquid dispersion medium in a gelated material 172 in a wet state. An ionic liquid is extremely low in vapor pressure and is able to maintain a gelated material in a wet state for a long period of time and accordingly, prevent the semiconductor nanoparticle phosphor's degradation attributed to the liquid dispersion medium's evaporation, and hence further improve the semiconductor nanoparticle phosphor's chemical stability and allow high emission characteristics to be maintained. Furthermore, the ionic liquid has an effect to electrostatically stabilize the semiconductor nanoparticle phosphor's surface and stably disperse the semiconductor nanoparticle phosphor without agglomeration, and a solidified body which presents high light emission efficiency and brightness is able to be obtained.

The ionic liquid which may be used for light emitting structure 71 of the sixteenth embodiment includes, for cation, ammonium based ion, phosphonium based ion, etc., such as imidazolium salts and pyridinium salts, and, for anion, halogen based ion such as bromide ion and triflate, boron based ion such as tetraphenyl borate, phosphorus based ion such as hexafluorophosphate, etc., however, other than these, it also includes a combination of ions existing as an ionic liquid. As specific examples of the ionic liquid, 2-(methacryloyloxy)-ethyltrimethyl ammonium bis(trifluoromethane sulfonyl)imide, 1-(3-acryloyloxy-propyl)-3-methylimidazolium bis(trifluoromethanesulfonyl) imide, N,N,N-trimethyl-N-propyl ammonium bis(trifluoromethane sulfonyl) imide, N,N-dimethyl-N-methyl-2-(2-methoxy ethyl) ammonium bis(trifluoromethane sulfonyl)imide, 1-allyl-3-butyl imidazolium tetrafluoroborate, 1-methyl-3-octylimidazolium hexafluoromethanephosphate, etc, are mentioned. Among these, an ionic liquid including impurity such as water tends to decrease the semiconductor nanoparticle phosphor's long-term stability, and accordingly, as the ionic liquid, it is preferable to use N,N,N-trimethyl-N-propyl ammonium bis(trifluoromethane sulfonyl) imide, as it is hydrophobic and is able to easily separate water.

(Light Emitting Structure of a Seventeenth Embodiment (Phosphor Containing Solidified Body))

FIG. 18 schematically shows a light emitting structure (a phosphor containing solidified body) 181 of a seventeenth embodiment of the present invention. Note that light emitting structure 181 of the example shown in FIG. 18 has a configuration similar to light emitting structure 151 of the example shown in FIG. 15 except for a portion. Furthermore, the light emitting structure of the seventeenth embodiment includes a translucent support, a liquid dispersion medium, and a semiconductor nanoparticle phosphor, as has been set forth above for the light emitting structure of the fourteenth embodiment.

As shown in FIG. 18, light emitting structure 181 of the seventeenth embodiment may have an outermost surface including a translucent covering layer 184. In the example shown in FIG. 18, a single type of semiconductor nanoparticle phosphor 182 is dispersed in a globular gelated material 183 and translucent covering layer 184 is formed on a surface of gelated material 183. Having the outermost surface including translucent covering layer 184 (in other words, holding a gelated material in a wet state inside a capsular covering layer) allows reduced oxygen and moisture permeability and is consequently able to significantly reduce or prevent the semiconductor nanoparticle phosphor's photooxidation and hence degradation and further enhance its chemical stability.

Covering layer 184 is not limited in material as long as it is translucent, however, a metal oxide, a silica-based material, or a similar translucent inorganic material is preferred. Furthermore, among these materials, covering layer 184 is preferably formed of an inorganic material having a band gap of 3.0 eV or more. The inorganic material of a metal oxide having a band gap of 3.0 eV or more and absorbing ultraviolet rays is exemplified for example by SiO₂, ZnO, TiO₂, CeO₂, SnO₂, ZrO₂, Al₂O₃, ZnO:Mg, etc. Among these, ZnO, TiO₂, Al₂O₃, CeO₂, and SnO₂ have a band gap close to 3.0 eV, and are thus able to absorb ultraviolet rays in a wide range (up to a range of ultraviolet rays close to visible light). Furthermore, SiO₂, ZrO₂, and ZnO:Mg have a band gap considerably larger than 3.0 eV, and accordingly, absorb only ultraviolet rays having a considerably short wavelength and transmit ultraviolet rays of a range close to visible light. Having an outermost surface including covering layer 184 including an inorganic material having a band gap of 3.0 eV or more is able to significantly reduce or prevent degradation by ultraviolet rays of the semiconductor nanoparticle phosphor and consequently enhance chemical stability. Note that in light emitting structure 181 of the seventeenth embodiment it is better if the inorganic material is an inorganic crystal.

(Light Emitting Structure of an Eighteenth Embodiment (Phosphor Containing Solidified Body))

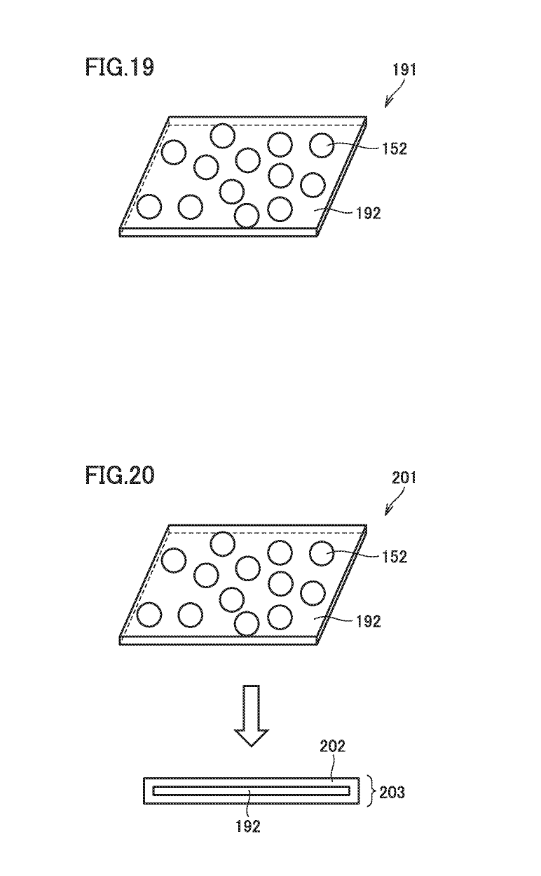

FIG. 19 schematically shows a light emitting structure (a phosphor containing solidified body) 191 of an eighteenth embodiment of the present invention. Note that light emitting structure 191 of the example shown in FIG. 19 has a configuration similar to that of light emitting structure 151 of the example shown in FIG. 15 except for a portion, and any similarly configured portion is identically denoted and will not be described repeatedly. Furthermore, the light emitting structure of the eighteenth embodiment includes a translucent support, a liquid dispersion medium, and a semiconductor nanoparticle phosphor, as has been set forth above for the light emitting structure of the fourteenth embodiment.

Light emitting structure 191 of the example shown in FIG. 19 includes a gelated material 192 in a wet state, that is formed in a sheet. While in light emitting structures 151, 161, 171 of the examples shown in FIG. 15 to FIG. 17, the gelated material in the wet state is assumed to have any shape, a gelated material in a wet state that is formed in a sheet, as shown in FIG. 19, is advantageous in that its flexible aspect is exploited to allow it to be also applicable to a place, such as a curved surface, requiring flexibility.

(Light Emitting Structure of a Nineteenth Embodiment (Phosphor Containing Solidified Body))

FIG. 20 schematically shows a light emitting structure (a phosphor containing solidified body) 201 of a nineteenth embodiment of the present invention. Note that light emitting structure 201 of the example shown in FIG. 20 has a configuration similar to that of light emitting structure 151 of the example shown in FIG. 15 except for a portion, and any similarly configured portion is identically denoted and will not be described repeatedly. Furthermore, the light emitting structure of the nineteenth embodiment includes a translucent support, a liquid dispersion medium, and a semiconductor nanoparticle phosphor, as has been set forth above for the light emitting structure of the fourteenth embodiment.

In the example shown in FIG. 20, gelated material 192 in a wet state that is the form of a sheet which is similar that shown in FIG. 19 is accommodated in a capillary 203. By this configuration, a base member 202 that configure capillary 203 is able to reduce degradation caused by external stimulation such as oxygen, moisture, light, etc., and hence further improve in chemical stability the semiconductor nanoparticle phosphor dispersed in the gelated material in the wet state. In the example shown in FIG. 20, base material 202 configuring capillary 203 is not limited in what material is used to produce it, as long as it has translucency, and metal oxides (SiO₂, Al₂O₃, TiO₂, etc.), a solid including an ionic liquid, etc. are mentioned.

It should be understood that the preferred embodiments and examples disclosed herein have been described for the purpose of illustration only and in a non-restrictive manner in any respect. The scope of the present invention is defined by the terms of the claims, rather than the embodiments described above, and is intended to include any modifications within the meaning and scope equivalent to the terms of the claims.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A light emitting structure comprising a translucent support, a liquid dispersion medium, and a semiconductor nanoparticle phosphor.

2. The light emitting structure according to claim 1, wherein the liquid dispersion medium is an ionic liquid.

3. The light emitting structure according to claim 1, wherein the liquid dispersion medium is nonvolatile.

4. The light emitting structure according to claim 1, wherein the liquid dispersion medium includes at least any of water, toluene, hexane, chloroform, trioctylamine, trioctyl phosphine oxide, 1-octadecene, and an ionic liquid.

5. The light emitting structure according to claim 1, wherein the semiconductor nanoparticle phosphor includes a plurality of light emission peaks.

6. The light emitting structure according to claim 1, wherein the semiconductor nanoparticle phosphor has a light emission wavelength in a range of about 380 nm to about 750 nm.

7. The light emitting structure according to claim 1, formed such that the translucent support has a pore, the liquid dispersion medium is held in the pore of the translucent support, and the semiconductor nanoparticle phosphor is dispersed in the liquid dispersion medium.

8. The light emitting structure according to claim 7, wherein the liquid dispersion medium is held in the pore by capillary force.

9. The light emitting structure according to claim 7, wherein the translucent support has a porous structure.

10. The light emitting structure according to claim 7, wherein the translucent support is capsular.

11. The light emitting structure according to claim 7, wherein the translucent support is a capillary.

12. The light emitting structure according to claim 7, further comprising a covering layer at least covering an opening of the pore.

13. The light emitting structure according to claim 7, wherein the translucent support has a gas barrier property.

14. A light emitting device comprising a light source and a wavelength converter in which the light emitting structure according to claim 7 is dispersed in a translucent medium.

15. The light emitting structure according to claim 1, wherein the translucent support includes a macromolecular chain forming a three-dimensional mesh structure, and one or more types of semiconductor nanoparticle phosphors are dispersed in a gelated material including the translucent support and the liquid dispersion medium and presented in a wet state.

16. The light emitting structure according to claim 15, wherein the translucent support is formed of at least any material selected from an acrylic acid based polymer, a vinyl based polymer, an epoxy based polymer, a polyvinylidene fluoride-hexafluoro propylene copolymer, a tetrafluoroethylene perfluoro [2-(fluorosulfonyl ethoxy) propylvinyl ether copolymer, poly (2-hydroxyethyl) methacrylate and Tetra-PEG.

17. The light emitting structure according to claim 15, having an outermost surface including a translucent covering layer.

18. The light emitting structure according to claim 17, wherein a material included in the covering layer is an inorganic material having a band gap equal to or greater than 3.0 eV.

19. The light emitting structure according to claim 15, provided in a form of a sheet.

20. The light emitting structure according to claim 19, accommodated in a capillary.
